(19) United States
(12) Patent Application Publication
(10) Pub. No.: US 2025/0192076 A1
(43) Pub. Date: Jun. 12, 2025

(54) SEMICONDUCTOR COMPONENT AND METHOD OF MANUFACTURING THE SAME

(71) Applicant: Hon Young Semiconductor Corporation, Hsinchu City (TW)

(72) Inventor: Liang-Ming LIU, Hsinchu City (TW)

(21) Appl. No.: 18/641,455

(22) Filed: Apr. 22, 2024

Related U.S. Application Data
(60) Provisional application No. 63/607,567, filed on Dec. 8, 2023.

(30) Foreign Application Priority Data
Mar. 14, 2024 (TW) 113109546

(51) Int. Cl. H01L 23/64; H01L 21/3215; H01L 29/08

(52) U.S. Cl. CPC H01L 23/647; H01L 21/3215; H10D 62/151

(57) ABSTRACT

Embodiments of this disclosure provide a semiconductor component, including a substrate, two conductive regions, a conductive connection layer, a well region and a source/drain region. The substrate has a surface. The two conductive regions are disposed in the substrate. The conductive connection layer is disposed on the substrate and below the two conductive regions, and the conductive connection layer is electrically connected to the two conductive regions. The well region is disposed in the substrate and between the two conductive regions, and a bottom surface of the well region contacts an upper surface of the two conductive regions. The source/drain region is disposed between adjacent two channel regions in the substrate and between the two conductive regions. In addition, this disclosure also provides a method of manufacturing a semiconductor component.

### CROSS-REFERENCE TO RELATED APPLICATION

This application claims priority to U.S. Provisional Application Ser. No. 63/607,567 filed Dec. 8, 2023, and Taiwan Application Serial Number 113109546, filed Mar. 14, 2024, the disclosures of which are incorporated herein by reference in their entireties.

### BACKGROUND

### Field of Invention

The present disclosure relates to a semiconductor component and a method of manufacturing the same.

### Description of Related Art

In the semiconductor field, reducing an on-resistance between a source and a drain of a transistor is called an on-resistance (Rₒₙ) to further reduce the power consumed in a resistor. Therefore, providing a method to reduce the on-resistance (Ron) of the transistor is still an issue of great concern in the industry.

### SUMMARY

Embodiments of this disclosure provide a method of manufacturing a semiconductor component, including the following steps. A substrate is provided, and the substrate has a surface. A doped stack is formed in the substrate, and the doped stack includes a first well connect layer, a conductive connection layer formed on the first well connection layer and a second well connection layer formed on the conductive connection layer. A mask is formed on the surface of the substrate to expose a plurality of portions of the surfaces. A doping process is performed on the plurality of portions exposed by the mask to form a doped region, and a doping depth reaches the second well connection layer to joint the doped region and the second well connection layer in a depth direction. Two conductive regions are formed in two first portions of the substrate to joint the two conductive regions and the conductive connection layer in the depth direction.

Some embodiments of this disclosure provide a semiconductor structure, including a substrate, at least two gate structures, a source/drain region, a first well connection layer and a conductive layer. The substrate has a first surface and a second surface opposite to each other. The at least two gate structures are disposed on the first surface of the substrate and includes two conductive regions. The source/drain region is disposed in the substrate between adjacent two channel regions and between the two conductive regions. The first well connection layer is disposed in the substrate. The conductive connection layer is disposed in the substrate and on the first well connection layer, an upper surface of the conductive connection layer contacts a bottom surface of each of the two conductive regions.

Some embodiments of this disclosure provide a semiconductor structure, including a substrate, two conductive regions, a conductive connection layer, a well region and a source/drain region. The substrate has a surface. The two conductive regions are disposed in the substrate. The conductive connection layer is disposed in the substrate and below the two conductive regions, and the conductive connection layer is electrically connected to the two conductive regions. The well region is disposed in the substrate and between the two conductive regions, and a bottom surface of the well region contacts a top surface of the conductive connection layer. The source/drain region is disposed in the substrate between adjacent two channel regions and between the two conductive regions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a top view of a semiconductor component according some embodiments of the present disclosure, and

FIGS. 2 to 7 are cross-sectional views taken along cross-section AA′ of FIG. 1 of a method of manufacturing a semiconductor component at various stages according some embodiments of the present disclosure.

### DETAILED DESCRIPTION

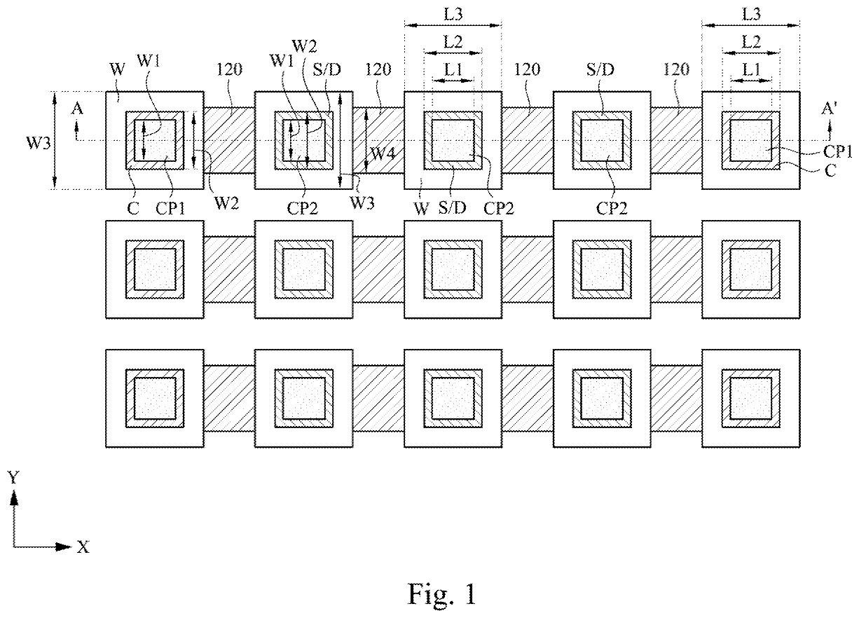

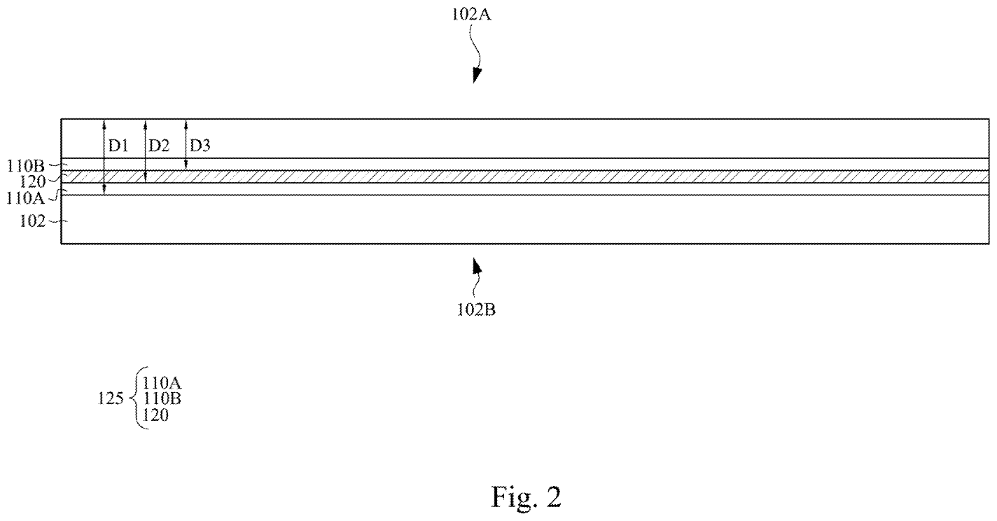

In order to reduce an on-resistance Rₒₙ of a semiconductor component of a semiconductor structure, embodiments of the present disclosure reduce a distance between the transistor elements (also called transistor units) by changing the distribution of an implantation structure (also called doping structure). Thus, a drain current may be increased, so that purposes of reducing the on-resistance Ron of the transistor element can be achieved. Accordingly, the embodiments of this disclosure are described below with reference to the figures. FIG. 1 is a top view of a semiconductor component according some embodiments of the present disclosure, and FIGS. 2 to 7 a are cross-sectional views taken along cross-section AA′ of FIG. 1 of a method of manufacturing a semiconductor component at various stages according some embodiments of the present disclosure.

Firstly, please refer to FIG. 2, a substrate 102 having a first surface 102A and a second surface 102B is provided, and a doped stack 125 is formed in the substrate 102. In some embodiments, the substrate 102 is, for example, a silicon carbide (SiC) substrate. The doped stack 125 includes a first well connection layer 110A, a conductive connection layer 120 formed on the first well connection layer 110A and a second well connection layer 110B formed on the conductive connection layer 120. The first well connection layer 110A has a first doping depth D1, the conductive connection layer 120 has a second doping depth D2, and the second well connection layer has a third doping depth D3. The first doping depth D1 is greater than the second doping depth D2, and the second doping depth D2 is greater than the third doping depth D3. In some embodiments, the first well connection layer 110A, the conductive connection layer 120 and the second well connection layer 110B include dopants. In some embodiments, the first well connection layer 110A, the conductive connection layer 120 and the second well connection layer 110B include a P-type dopant. In some embodiments, the first well connection layer 110A and the second well connection layer 110B have the same doping concentration, while the conductive connection layer 120 has a doping concentration different from the doping concentration of the first well connection layer 110A and the second well connection layer 110B.

In some embodiments, a mask (not shown) is formed on the substrate 102, and the mask exposes a plurality of portions of the first surface 102A of the substrate 102. Subsequently, through a doping process, the dopants are implanted into the substrate 102 at position of the exposed portions of the substrate 102 to form a well connection layer, and then the mask is removed. In addition, the well connection layer has a first doping depth D1, a doping thickness and a first doping concentration. Next, another mask (not shown) is formed on the substrate 102 to expose the portions of the first surface 102A of the substrate 102. Then, through a doping process, a dopant is implanted into the substrate 102 at the positions of the exposed portions of the substrate 102 to form the conductive connection layer 120 in the well connection layer. The conductive connection layer 120 has a second doping depth D2, a second doping thickness and a second doping concentration. The well connection layer is separated into the first well connection layer 110A (near to the second surface 102B of the substrate 102) and the second well connection layer 110B (near to the first surface 102A of the substrate 102) by the conductive connection layer 120. Furthermore, the first doping thickness is greater than the second doping thickness, and the first doping concentration is different from the second doping concentration.

In some embodiments, a mask (not shown) is formed on the substrate 102, and the mask is exposed on the plurality of portions of the first surface 102A of the substrate 102. Subsequently, the dopant is implanted into the substrate 102 through the doping process with a first yellow light development energy to form a first well connection layer 110A. Next, the dopant is implanted into the substrate 102 through a second yellow light development energy to form the conductive connection layer 120 on the first well connection layer 110A. Then, the dopant is implanted into the substrate 102 through a third yellow light development energy to form the second well connection layer 110B on the conductive connection layer 120.

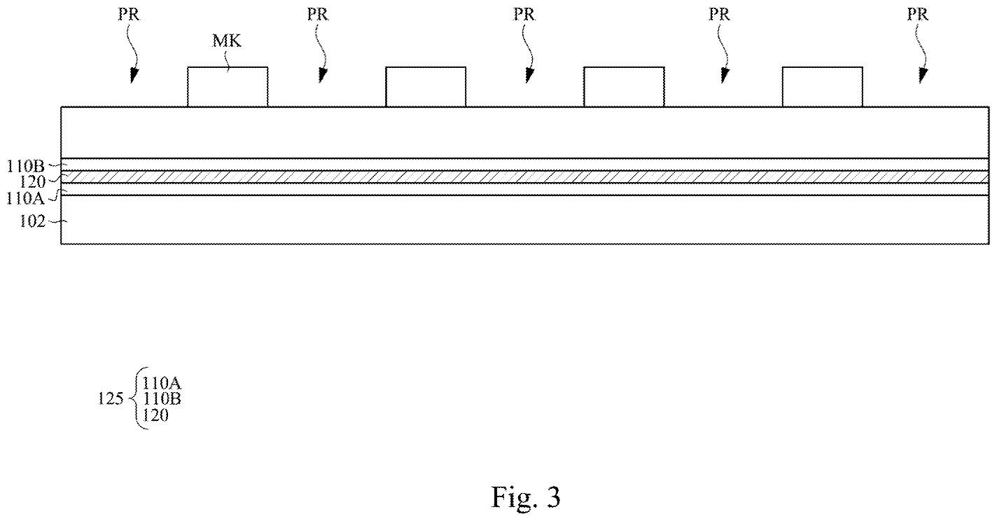

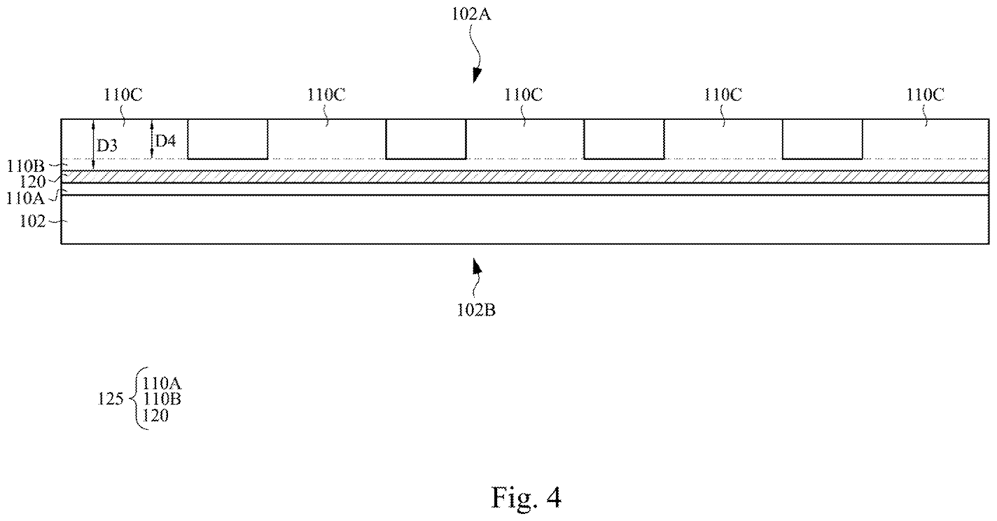

Next, as shown in FIG. 3, a mask MK is formed on the first surface 102A of the substrate 102 to expose a plurality of portions PR of the first surface 102A (such as in FIG. 2) of the substrate 102. Further, as shown in FIG. 4, a doping process is performed in the exposed portions PR of the substrate 102, and a dopant is implanted to form a doped region 110C in the substrate 102. Additionally, a doping depth of the doped region 110C is a fourth doping depth D4 to reach the second well connection layer 110B, so that the doped region 110C and the second well connection layer 110B are jointed in a depth direction. Subsequently, the mask (the mask MK shown in FIG. 3) is removed, and undoped portions are exposed. In some embodiments, the dopant doped in doped region 110C is a P-type dopant. In some embodiments, a doping concentration of the doped region 110C is the same as a doping concentration of the second well connection layer 110B, and a doping type of the doped region 110C is the same as a doping type of the second well connection layer 110B.

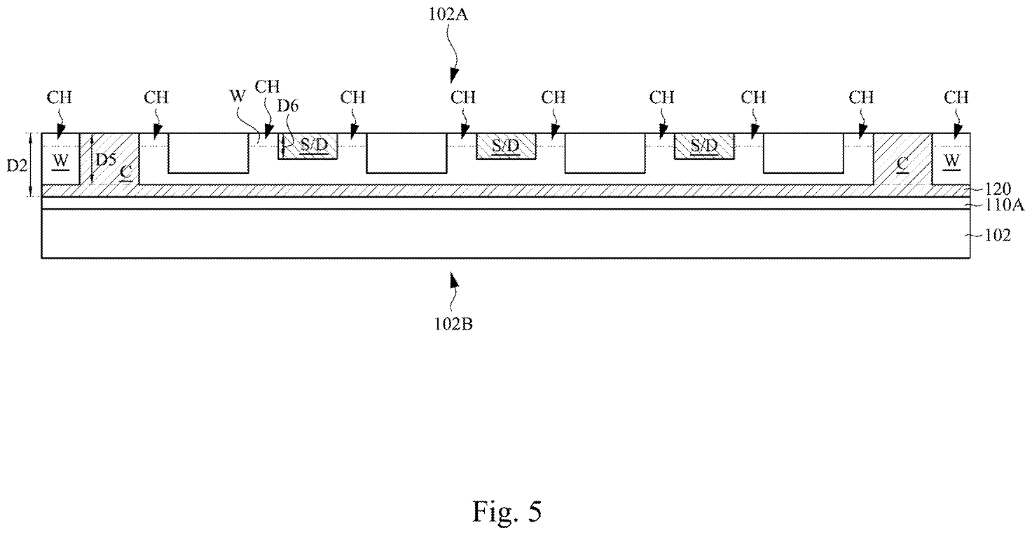

As shown in FIG. 5, conductive regions C are respectively formed in two first portions of the first surface 102A of the substrate 102. A fifth doping depth D5 of each of the conductive regions C is reached the conductive connection layer 120, so that each of the conductive regions C and the conductive connection layer 120 are jointed in the depth direction. Additionally, a plurality of well regions W are formed between the conductive regions C and on the conductive connection layer 120, and a plurality of channel regions CH are formed in the well regions W. Moreover, a plurality of source/drains S/D are formed in a plurality of second portions of the first surface 102A of the substrate 102. The second portions are disposed between the two first portions. Each of the source/drains S/D has a sixth doping depth D6.

In some embodiments, a doping type of each of the conductive regions C is different from a doping type of the source/drain region S/D. In some embodiments, a doping type of the conductive region C is a P-type dopant, and a doping type of the source/drain regions S/D is an N-type dopant. In some embodiments, a doping depth of the conductive region C is different from a doping depth of the source/drain region S/D. That is, a height of a bottom surface of the source/drain region S/D is higher than a height of a top surface of the conductive region C. In some embodiments, the fifth doping depth D5 of the conductive region C is greater than the sixth doping depth D6 of the source/drain region S/D.

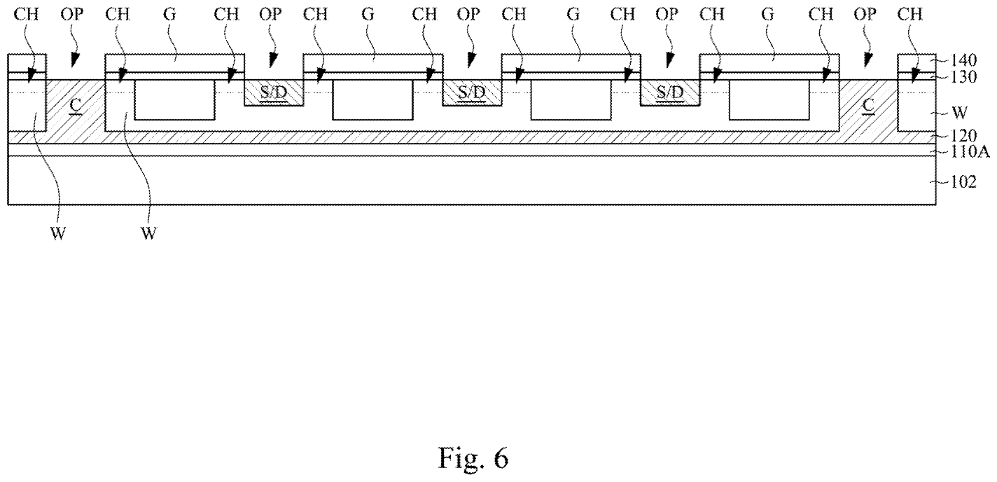

As shown in FIG. 6, an insulating layer 130 is deposited on the first surface 102A of the substrate 102. Then, a conductive layer 140 is deposited on the insulating layer 130. Next, a mask (not shown) is formed on the conductive layer 140 to expose a plurality of portions of a surface of the conductive layer 140, and the exposed portions are corresponding to positions of the conductive regions C and the source/drain regions S/D. Thus, a plurality of contact openings OP and a plurality of gate structures G are formed through a photolithography process and an etching process. In some embodiments, the insulating layer 130 includes an oxide, such as silicon dioxide, hafnium oxide, or titanium oxide. In some embodiments, the conductive layer 140 includes polysilicon.

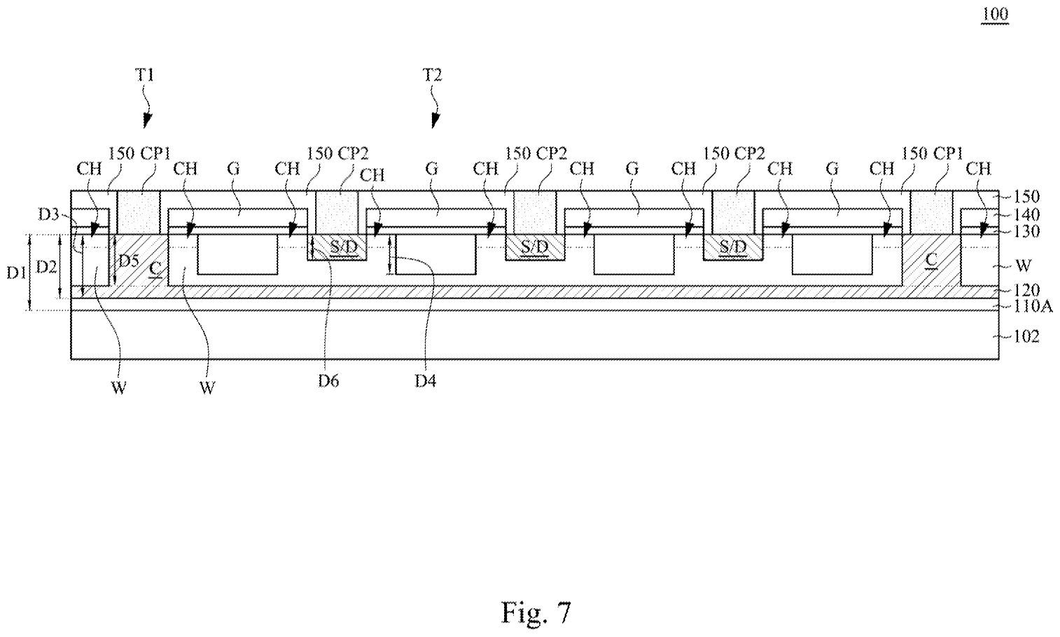

As shown in FIG. 7, a first contact CP1 is formed in the contact opening (such as each of the contact openings OP shown in FIG. 6) on each of the conductive regions C, and a first transistor structure T1 is formed. A second contact CP2 is formed in the contact opening (such as each of the contact openings OP shown in FIG. 6) on each of the source/drain regions S/D, and a second transistor structure T2 is formed. Specifically, the insulating layer 150 is deposited in the contact opening (such as each of the contact openings OP shown in FIG. 6) and on the conductive layer 140. Subsequently, the conductive layer 140 is patterned to form openings (not shown) on the conductive regions C and the source/drain regions S/D through an etching process. Moreover, a width of each of the openings is smaller than a width of the contact opening (such as each of the contact openings shown in FIG. 6). Then, a conductive material is filled into each of the openings on the conductive regions C to form the first contact CP1, so as to form the first transistor structure T1. Furthermore, the conductive material is filled into each of the openings on the source/drain regions S/D to form the second contact CP2, so as to form the second transistor structure T2. Therefore, a bottom surface of the first contact CP1 contacts a top surface of each of the conductive regions C, and a bottom surface of the second contact CP2 contacts a top surface of each of the source/drain regions S/D. Moreover, side surfaces of the first contact point CP1 and the second contact point CP2 are surrounded by the insulating layer 150. A bottom surface of the insulating layer 150 disposed on the conductive region C or the source/drain region S/D also contacts the top surface of each of the conductive regions C or the top surface of each of the source/drain regions S/D.

In some embodiments, the first transistor structure T1 is a P-type transistor structure T1, and the second transistor structure T2 is an N-type transistor structure T2. In some embodiments, the semiconductor component 100 formed by the first transistor structure T1 and the second transistor structure T2 is configured in a metal-oxide-semiconductor field-effect transistor (MOSFET), especially configured in depletion MOSFET (depletion MOSFET, DMOSFET).

Through the method of manufacturing the semiconductor component provided by this disclosure, the first transistor structure T1 and the second transistor structure T2 are connected in series through the conductive connection layer 120 and the conductive regions C in a manner of separating the conductive regions C and the source/drain regions S/D. In this way, simply a small number of the contacts are connected to the conductive regions C, and the remaining contacts are connected to the source/drain regions S/D. Therefore, the purposes of decreasing the spacing between transistor structures to reduce the on-resistance Ron, and further reduce the contact resistance.

As shown in FIG. 1 and FIG. 7, embodiments of this disclosure provide a semiconductor component 100. The semiconductor component 100 includes a substrate 102 having a first surface 102A and a second surface 102B, a first well connection layer 110A, a conductive connection layer 120, a second well connection layer 110B, a well region W, two P-type transistor structures T1 and an N-type transistor structure T2.

The first well connection layer 110A is disposed in the substrate 102 and near to the second surface 102B. The first well connection layer 110A has a first doping depth D1, and the first well connection layer 110A has a first doping concentration. In some embodiments, the first well connection layer 110A includes a P-type dopant.

The conductive connection layer 120 is disposed in the substrate 102 and on the first well connection layer 110A. The conductive connection layer 120 has a second doping depth D2, and the conductive connection layer 120 has a second doping concentration. The second depth D2 is smaller than the first depth D1, and the second doping concentration is different from the first doping concentration. In some embodiments, the conductive connection layer 120 includes a P-type dopant.

The second well connection layer 110B is disposed in the substrate and on the conductive connection layer 120. The second well connection layer 110B has a third doping depth D3, and the second well connection layer 110B has the first doping concentration. Additionally, the third doping depth D3 is smaller than the second doping depth D2. In some embodiments, the second well connection layer 110B includes a P-type dopant.

The two P-type transistor structures T1 are disposed on the substrate 102. The well region W and the channel regions CH are disposed in the substrate 102 on opposite sides of the two P-type transistor structures T1, respectively. Each of the two P-type transistor structures T1 includes a conductive region C between the channel regions CH, a gate structure G on the substrate 102 and the channel regions CH and a first contact CP1 on the conductive region C. A bottom surface of the first contact CP1 contacts a top surface of the conductive region C, a side surface of the first contact CP1 is surrounded by an insulating layer 150. The conductive region C has a fifth depth D5. A bottom surface of conductive region C contacts a top surface of the conductive connection layer 120, so that the conductive region C is electrically connected to the conductive connection layer 120. In some embodiments, the conductive region C includes a P-type dopant. In some embodiments, a doping concentration of the conductive region C is the same as a doping concentration of the conductive connection layer 120, and a doping type of the conductive region C is the same as a doping type of the conductive connection layer 120.

Further, as shown in FIG. 1, the first contact CP1 of the P-type transistor structure T1 has a first length L1 (in the x direction) and a first width W1 (in the y direction). In some embodiments, the first length L1 is equal to the first width W1. In some embodiments, the first width W1 is 0.8 micrometers (μM), and the first length L is 0.8 μM. The conductive region C has a second length L2 (in the x direction) and a second width W2 (in the y direction). In some embodiments, the second length L2 is equal to the second width W2. In some embodiments, the first length L1 is less than the second length L2, and the first width W1 is less than the second width W2. In some embodiments, the second length L2 is 1 μM, and the second width W2 is 1 μM. In addition, in the x direction, measured from a first side of the well region W on one side of the P-type transistor structure T1 to a second side of the well region W on the other side of the P-type transistor structure T1 is a third length L3, and in the y direction, measured from a first side of the well region W on one side of the P-type transistor structure T1 to a second side of the well region W on the other side of the P-type transistor structure T1 is the third Width W3. In some embodiments, the third length L3 is equal to the third width W3. In some embodiments, the third length L3 is greater than the second length L2, and the third width W3 is greater than the second width W2. In some embodiments, the third width W3 is 2 μM, and the third length L3 is 2 μM. Further, in the y direction, the conductive connection layer 120 has a fourth width W4. In some embodiments, the fourth width W4 is greater than the second width W2, and the fourth width W4 is less than the third width W3. In some embodiments, the fourth width W4 is 1.2 μM.

The N-type transistor structure T2 is disposed on the substrate 102 and between the two P-type transistor structures T1. The well region W and the channel regions CH are disposed in the substrate 102 on opposite sides of the N-type transistor structure T2, respectively. In addition, the N-type transistor structure T2 includes a source/drain region S/D between the channel regions CH, a gate structure G on the substrate 102 and the channel region CH, and a second contact CP2 on the source/drain region S/D. In addition, a bottom surface of the second contact CP2 contacts a top surface of the source/drain region S/D, and a side surface of the second contact CP2 is surrounded by the insulating layer 150. The source/drain region S/D has a sixth doping depth D6, and the sixth doping depth D6 is smaller than the fifth doping depth D5. In some embodiments, the source/drain region S/D includes an N-type dopant.

Further, as shown in FIG. 1, since the difference between the N-type transistor structure T2 and the P-type transistor structure T1 is the doping types of the conductive region C and the source/drain region S/D. As well, in the top view of FIG. 1, other structural features of the N-type transistor structure T2 and the P-type transistor structure T1 (such as the second contact CP2 of the N-type transistor structure T2, the cross length of the source/drain regions S/D and the well region W, and the relationship and between the second width W2 of the source/drain region S/D and the fourth width W4 of the conductive connection layer 120 and between the third width W3 and the fourth width W4 of the conductive connection layer 120) is substantially similar, so it will not be repeated here.

It is worth mentioning that, as mentioned above, the well region W is disposed between the conductive regions C, and a bottom surface of the well region W contacts the top surface of the conductive connection layer 120. The third doping depth D3 of the well region W is smaller than the fifth doping depth D5 of the conductive region C.

As mentioned above, through the contact between the conductive connection layer and the conductive region, and through the contact between the well region and the second well connection layer, the size of the contact can no longer be limited by the critical dimensions (CD) of the conductive region and the source/drain region. Therefore, the purpose of decreasing the spacing between the transistor structures to reduce the on-resistance Rₒₙ can be achieved, and the contact resistance can be further reduced.

What is claimed is:

1. A method of manufacturing a semiconductor component, comprising:
providing a substrate, and the substrate has a surface;
forming a doped stack in the substrate, wherein the doped stack comprises a first well connection layer, a conductive connection layer formed on the first well connection layer and a second well connection layer formed on the conductive connection layer;
forming a mask on the surface of the substrate to expose a plurality of portions of the surface;
performing a doping process on the plurality of portions exposed by the mask to form a doped region, and a doping depth reaches the second well connection layer to joint the doped region and the second well connection layer in a depth direction; and
forming two conductive regions in two first portions of the substrate to joint the two conductive regions and the conductive connection layer in the depth direction.

2. The method of claim 1, further comprising:
forming at least one source/drain region and at least two channel regions in a plurality of second portions of the substrate.

3. The method of claim 2, further comprising:
forming a plurality of gate structures on a plurality of third portions of the surface of the substrate, and comprising:
forming a first insulating layer on the surface of the substrate;
forming a conductive layer on the first insulating layer; and
patterning the first insulating layer and the conductive layer.

4. The method of claim 2, wherein a doping type of the two conductive regions is a P-type dopant, and a doping type of the at least one source/drain region is an N-type dopant.

5. The method of claim 2, wherein a doping depth of the two conductive regions is different from a doping depth of the at least one source/drain region.

6. A semiconductor component, comprising:
a substrate having a first surface and a second surface opposite to each other;
at least two gate structures disposed on the first surface of the substrate, and comprising two conductive regions;
a source/drain region disposed in the substrate between adjacent two channel regions and between the two conductive regions;
a first well connection layer disposed in the substrate; and
a conductive connection layer disposed in the substrate and on the first well connection layer, wherein an upper surface of the conductive connection layer contacts a bottom surface of each of the two conductive regions.

7. The semiconductor component of claim 6, further comprising:
two first contacts disposed on the two conductive regions; and
at least one second contact disposed on the source/drain region.

8. The semiconductor component of claim 7, wherein the two first contacts comprises:
a conductive material disposed on the source/drain region; and
an insulating layer disposed on the source/drain region and surrounding a side surface of the conductive material.

9. The semiconductor component of claim 7, wherein a height of a bottom surface of the source/drain region is greater than a height of a top surface of the two conductive regions.

10. The semiconductor component of claim 6, further comprising:
a second well connection layer disposed in the substrate and on the conductive connection layer, wherein a top surface of the second well connection layer contacts the two channel regions between the source/drain region.

11. The semiconductor component of claim 6, wherein in a top view, the source/drain region has a source-drain width in a first direction, the conductive connection layer has a connection width, and the connection width is greater than the source-drain width.

12. The semiconductor component of claim 6, wherein the two conductive regions comprise a P-type dopant, and the source/drain region comprises an N-type dopant.

13. A semiconductor component, comprising:
a substrate having a surface;
two conductive regions disposed in the substrate;
a conductive connection layer disposed in the substrate and below the two conductive regions, wherein the conductive connection layer is electrically connected to the two conductive regions;
a well region disposed in the substrate and between the two conductive regions, wherein a bottom surface of the well region contacts a top surface of the conductive connection layer; and
a source/drain region disposed in the substrate between adjacent two channel regions and between the two conductive regions.

14. The semiconductor component of claim 13, further comprising:
two conductive contacts disposed on the two conductive regions and jointed to the gate structure, wherein a bottom surfaces of each of the two conductive contacts respectively contacts a top surface of each of the two conductive regions.

15. The semiconductor component of claim 13, further comprising:
a well connection layer disposed in the substrate and below the conductive connection layer, and the well connection layer electrically connected to the conductive connection layer.
